(19) United States
(12) Patent Application Publication
(10) Pub. No.: US 2012/0159967 A1
(43) Pub. Date: Jun. 28, 2012

(54) THERMOELECTRIC APPARATUS

(75) Inventors: Hyoseok LEE, Gyeonggi-do (KR); Changhwan Park, Gyeonggi-do (KR); Subong Jang, Gyeonggi-do (KR); Younghoon Kwak, Gyeonggi-do (KR); Yongil Kwon, Gyeonggi-do (KR)

(73) Assignee: SAMSUNG ELECTRO-MECHANICS CO., LTD.

(21) Appl. No.: 13/294,757

(22) Filed: Nov. 11, 2011

(30) Foreign Application Priority Data
Dec. 22, 2010 (KR) 10-2010-0132429

(51) Int. Cl. F25B 21/04; H01L 35/28

(52) U.S. Cl. 62/3.3; 136/200; 62/3.7

(57) ABSTRACT

Disclosed herein is a thermoelectric apparatus, including: a power supply unit outputting AC power; a plurality of thermoelectric modules including substrates, electrodes and thermoelectric elements; a rectifier configured of a pair of diodes each connected in series at one side of the respective thermoelectric modules, the diodes having a different direction; and a path selection unit selecting any one of the pair of diodes having a different direction and connecting the diode to the power supply unit.

### CROSS REFERENCE(S) TO RELATED APPLICATIONS

This application claims the benefit under 35 U.S.C. Section 119 of Korean Patent Application Serial No. 10-2010-0132429, entitled “Thermoelectric Apparatus” filed on Dec. 22, 2010, which is hereby incorporated by reference in its entirety into this application.

### BACKGROUND OF THE INVENTION

1. Technical Field

The present invention relates to a thermoelectric apparatus, and more particularly, to a thermoelectric apparatus capable of performing heating function and cooling function, while improving utilization of AC power.

2. Description of the Related Art

Due to the increase in use of fossil energy that causes global warming and exhaustion of energy, more researches into a thermoelectric apparatus capable of efficiently using energy have been recently conducted.

The thermoelectric apparatus may be used as a power generator using a Seebeck effect that electromotive force is generated when both ends of the thermoelectric element have a difference in temperature or a heater or a cooler using a Peltier effect that one end of the thermoelectric apparatus generates heat and the other end thereof absorbs heat when power is applied to the thermoelectric element.

In the case of the heater and the cooler using the Peltier effect, a hot side and a cold side are changed according to a direction of current applied to the thermoelectric apparatus, such that DC power is required.

In other words, when the AC power is used by being applied to the thermoelectric module as it is, the direction of current applied to the thermoelectric element is frequently changed according to the frequency of AC power and thus the positions of the hot side and the cold side are also frequently changed, and as a result, it is impossible to function as a heater and a cooler.

Therefore, a technology for installing an analog-digital converter or the like converting AC power to DC power in a thermoelectric apparatus has been proposed in order to use AC power instead of the DC power.

U.S. Patent Laid-Open Publication No. 2008-0314430 discloses a method of converting AC input into DC output using a rectifier to supply the DC output to a thermoelectric apparatus.

According to the related art, a system of implementing the thermoelectric apparatus becomes complicated and the manufacturing costs thereof are increased.

In addition, the thermoelectric apparatus may be used for cooling or heating an object using the Peltier effect. In consideration of gradually broadening fields that utilize the thermoelectric apparatus, there is a demand for selectively using a cooling function and a heating function, as needed. However, the thermoelectric apparatuses according to the related art may switch a cooling function and a heating function only by changing a power supply unit, a circuit or the like, or turning the thermoelectric module over, thereby causing inconvenience in actual use thereof.

### SUMMARY OF THE INVENTION

An object of the present invention is to provide a thermoelectric apparatus capable of performing thermoelectric function by receiving AC power, without increasing in volume thereof or increasing in thermoelectric elements, using the entire phase of the AC power in implementing the thermoelectric function, and selectively implementing a heating or cooling phenomenon on the same surface of the thermoelectric apparatus.

According to an exemplary embodiment of the present invention, there is provided a thermoelectric apparatus, including: a power supply unit outputting AC power; a plurality of thermoelectric modules including substrates, electrodes and thermoelectric elements; a rectifier configured of a pair of diodes each connected in series at one side of the respective thermoelectric modules, the diodes having a different direction; and a path selection unit selecting any one of the pair of diodes having a different direction and connecting the diode to the power supply unit.

The plurality of thermoelectric modules may share at least one substrate.

The rectifier may be provided in each of the thermoelectric modules.

The path selection unit may be provided in each of the thermoelectric modules.

The rectifier may be connected to an electrode contacting only an N-type semiconductor of the plurality of thermoelectric modules.

The rectifier may be connected to an electrode contacting only a P-type semiconductor of the plurality of thermoelectric modules.

According to another exemplary embodiment of the present invention, there is provided a thermoelectric apparatus, including: a power supply unit outputting AC power; a first thermoelectric module and a second thermoelectric module including substrates, electrodes and thermoelectric elements; a first diode connected in series to one side of the first thermoelectric module; a second diode connected in series to one side of the first thermoelectric module, having a direction opposite to the first diode; a third diode connected in series to one side of the second thermoelectric module; a fourth diode connected in series to one side of the second thermoelectric module, having a direction opposite to the third diode; a first switch connecting one selected from the first diode and the second diode to the power supply unit; and a second switch connecting one selected from the third diode and the fourth diode to the power supply unit.

The first thermoelectric module and the second thermoelectric module may share at least one substrate.

The first diode and the second diode may be provided in the first thermoelectric module, and the third diode and the fourth diode may be provided in the second thermoelectric module.

The first switch may be provided in the first thermoelectric module, and the second switch may be provided in the second thermoelectric module.

The first diode and the second diode may be connected to an electrode contacting only an N-type semiconductor of the first thermoelectric module, and the third diode and the fourth diode may be connected to an electrode contacting only an N-type semiconductor of the second thermoelectric module.

The first diode and the second diode may be connected to an electrode contacting only a P-type semiconductor of the first thermoelectric module, and the third diode and the fourth diode may be connected to an electrode contacting only a P-type semiconductor of the second thermoelectric module.

The polarity of the terminal of the first diode connected to the electrode of the first thermoelectric module may be the same as that of the third diode connected to the electrode of the second thermoelectric module, and the polarity of the terminal of the second diode connected to the electrode of the first thermoelectric module may be the same as that of the fourth diode connected to the electrode of the second thermoelectric module.

When the first switch is connected to the first diode, the second switch may be connected to the third diode, and when the first switch is connected to the second diode, the second switch may be connected to the fourth diode.

### BRIEF DESCRIPTION OF THE DRAWINGS

FIG. 1 is a concept diagram showing a driving principle of a thermoelectric module;

FIG. 2 is a diagram showing a configuration of a thermoelectric apparatus according to an exemplary embodiment of the present invention; and

FIG. 3 is a graph showing a waveform of AC power output from the power supply unit of FIG. 2.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an operation of the present invention will be described in more detail with reference to the accompanying drawings.

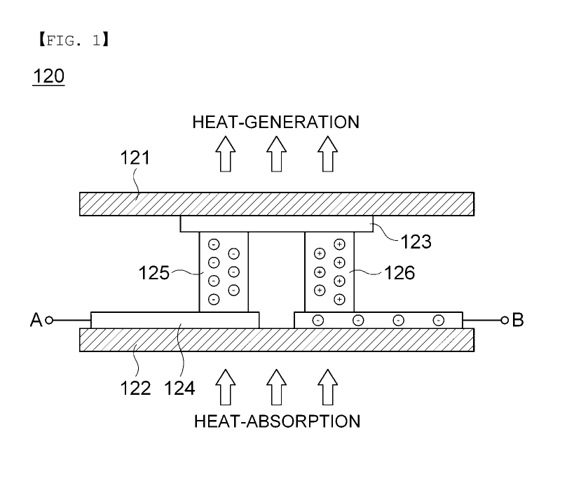

FIG. 1 is a concept diagram showing a driving principle of a thermoelectric module.

Referring to FIG. 1, a thermoelectric module 120 is configured to include a first substrate 121 and a second substrate 122, a first electrode 123 and a second electrode 124 provided at inner sides of the first substrate and the second substrate, and thermoelectric elements 125 and 126 provided between the first electrode and the second electrode.

The first and second substrates 121 and 122 are spaced apart from each other at a predetermined interval and disposed to be opposite to each other.

At this time, the first and second substrates 121 and 122 may be made of an insulating material having excellent thermal conductivity, such as ceramic or the like.

Meanwhile, the first and second electrodes 123 and 124 may include at least any one of Ag, Au, Pt, Sn, or Cu. At this time, the first and second electrodes 123 and 124 may be formed in a single layer structure of a single component or a multi-layer structure including at least two layers. Alternatively, the first and second electrodes 123 and 124 may be formed in a single layer structure of a mixture of at least two components.

The thermoelectric elements 125 and 126 are interposed between the first and second electrodes 123 and 124 and are bonded to the first and second electrodes 123 and 124. At this time, each of the first and second electrodes 123 and 124 is embedded in the first and second substrates 121 and 122 and the planarization of the first and second substrates 121 and 122 is maintained, such that the bonding stability between the thermoelectric elements 125 and 126 and the first and second electrodes 123 and 124 can be secured.

In addition, the electric resistance and the thermal conductivity can be lowered due to the bonding stability between the thermoelectric elements 125 and 126 and the first and second electrodes 123 and 124, such that the figure of merit of the thermoelectric module 120 can be increased.

The thermoelectric elements 125 and 126 are configured to include an N-type semiconductor 125 and a P-type semiconductor 126.

Herein, the N-type semiconductor 125 and the P-type semiconductor 126 may be alternately arranged on the same plane. At this time, a pair of N-type semiconductor 125 and P-type semiconductor 126 may be electrically connected by the first electrode 123 disposed at the upper surfaces thereof, and another pair of N-type semiconductor 125 and P-type semiconductor 126 next thereto may be electrically connected by the second electrode 124 disposed at the lower surfaces thereof.

When power is applied to the thermoelectric module 120 through contact points A and B, electrons (e−) and holes (h+), carriers, are generated from an electrode at one surface, such that the electrons flow to the N-type semiconductor 125 and the holes flow to the P-type semiconductor 126, thereby transferring heat.

The carriers are recombined on the electrode at the opposite surface and heat-absorption is generated in the second substrate 122 adjacent to the second electrode 124 from which the carriers are generated. In addition, heat-generation is generated from the first substrate adjacent to the first electrode 123 on which the carriers are recombined, wherein the portions in which heat-absorption is generated may be called a cold side and heat-generation is generated may be called as a hot side.

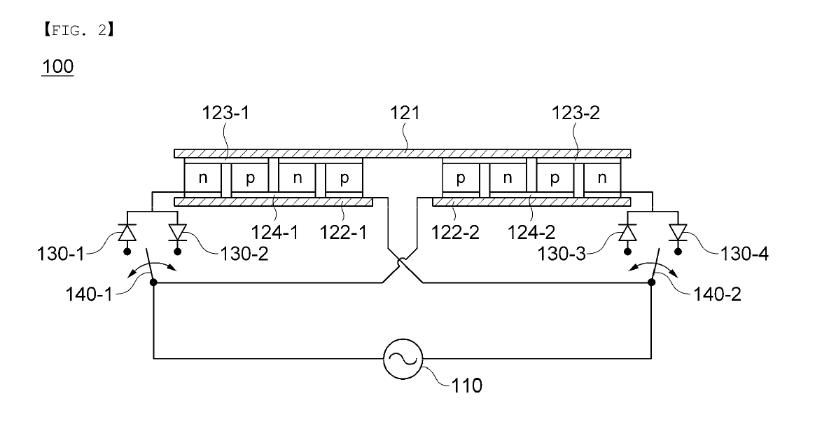

FIG. 2 is a diagram showing a configuration of a thermoelectric apparatus according to an exemplary embodiment of the present invention.

Referring to FIG. 2, a plurality of thermoelectric modules, that is, a first thermoelectric module 120-1 and a second thermoelectric module 120-2, are connected to each other, such that the thermoelectric elements thereof are arranged to be opposite.

For example, the first thermoelectric module 120-1 may be configured such that the first thermoelectric element may be arranged in sequence of N type—P type—N type− P type semiconductors. The second thermoelectric module 120-2 may be configured such that the second thermoelectric element may be arranged in sequence of P type—N type—P type− N type semiconductors.

The reason why the plurality of thermoelectric modules 120a to 120n are connected, having different polarities, is to be used in driving the thermoelectric module by receiving AC power having both polarities to be described below.

Next, the rectifier 130 may be configured to include a first diode to a fourth diode 130-1, 130-2, 130-3, and 130-4.

In addition, a path selection unit 140 (140-1 and 140-2) may be configured to include a first switch and a second switch.

The rectifier 130 (130-1 to 130-4) serves to control AC power each having a different polarity to be applied to the plurality of thermoelectric modules 120-1 and 120-2.

The diodes are connected to each of the plurality of thermoelectric modules 120-1 to 120-2 in series and a pair of diodes connected to one thermoelectric module is connected in parallel such that the polarities thereof are opposite to each other.

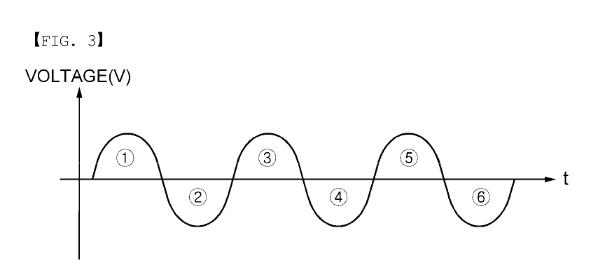

FIG. 3 is a graph showing one example of AC power output from the power supply unit of FIG. 2. Referring to FIGS. 2 and 3, the cathode of the first diode 130-1 is connected to the first thermoelectric module 120-1 and the anode of the first diode 130-1 is disposed at a terminal side connected to the first switch 140-1, and the anode of the second diode 130-2 is connected to the first thermoelectric module 120-1, reverse to the first diode 130-1, and the cathode thereof is disposed at a terminal side connected to the first switch 140-1.

Similarly, the cathode of the third diode 130-3 is connected to the second thermoelectric module 120-2 and the anode of the third diode 130-3 is disposed at a terminal side connected to the second switch 140-2, and the anode of the fourth diode 130-4 is connected to the second thermoelectric module 120-2, reverse to the third diode 130-3, and the cathode thereof is disposed at a terminal side connected to the second switch 140-2.

Next, the operation principle of the thermoelectric apparatus according to an exemplary embodiment of the present invention will be described.

Referring to FIGS. 2 and 3, first, when the first switch 140-1 is connected to the first diode 130-1 and the second switch 140-2 is connected to the third diode 130-3, the diodes flow from an anode terminal to a cathode terminal. Therefore, when positive AC power such as \textcircled{1}, \textcircled{3}, \textcircled{5} of FIG. 3. is applied from the power supply unit 110, the first substrate 121 side of the first thermoelectric module 120-1 becomes a cold side and the second substrate 122-1 side thereof becomes a hot side, thereby being operated.

In addition, when negative AC power such as \textcircled{2}, \textcircled{4}, \textcircled{6} of FIG. 3 is applied from the power supply unit 110, the first substrate 121 side of the second thermoelectric module 120-2 becomes a cold side and the second substrate 122-1 side thereof becomes a hot side, thereby being operated.

That is, the first thermoelectric module 120-1 is operated in the case of the positive AC power, and the second thermoelectric module 120-2 is operated in the case of the negative AC power, such that a cooling phenomenon is generated at the first substrate 121 side.

Meanwhile, when the first switch 140-1 is connected to the second diode 130-2 and the second switch 140-2 is connected to the fourth diode 130-4, if negative AC power such as \textcircled{2}, \textcircled{4}, \textcircled{6} of FIG. 3 is applied from the power supply unit 110, the first substrate 121 side of the first thermoelectric module 120-1 becomes a hot side and the second substrate 122-1 side becomes a cold side, thereby being operated.

In addition, when positive AC power such as \textcircled{1}, \textcircled{3}, \textcircled{5} of FIG. 3 is applied from the power supply unit 110, the first substrate 121 side of the second thermoelectric module 120-2 becomes a hot side and the second substrate 122-1 side thereof becomes a cold side, thereby being operated.

As described above, in the thermoelectric apparatus according to an exemplary embodiment of the present invention, a specific surface (for example, the first substrate 121) of the thermoelectric module may be used as a hot side or a cold side according to a selection of the path selection part (the first switch 140-1 and the second switch 140-2).

In addition, the plurality of thermoelectric modules (the first thermoelectric module 120-1 and the second thermoelectric module 120-2) are provided, such that the thermoelectric module 120 may be operated in both cases in which the phase of the AC power is positive and negative, thereby improving energy efficiency and thermoelectric performance.

Meanwhile, the exemplary embodiment of the present invention describes a case in which the first thermoelectric module 120-1 and the second thermoelectric module 120-2 share the first substrate 121; however, they may share the second substrate 122 and may also share both substrates.

In addition, miniaturization of the thermoelectric apparatus may be improved by including the first diode 130-1 and the second diode 130-2 in the first thermoelectric module 120-1 and including the third diode 130-3 and the fourth diode 130-4 in the second thermoelectric module 120-2.

In addition, the miniaturization of the thermoelectric apparatus may be improved by including the first switch 140-1 in the first thermoelectric module 120-1 and by including the second switch 140-2 in the second thermoelectric module 120-2.

In addition, the first diode 130-1 and the second diode 130-2 may be connected to an electrode connecting only an N-type semiconductor 125 of the first thermoelectric module 120-1 and the third diode 130-3 and the fourth diode 130-4 may be connected to an electrode contacting only an N-type semiconductor 125 of the second thermoelectric module 120-2.

In addition, the first diode 130-1 and the second diode 130-2 may be connected to an electrode connecting only a P-type semiconductor 126 of the first thermoelectric module 120-1 and the third diode 130-3 and the fourth diode 130-4 may be connected to an electrode contacting only a P-type semiconductor 126 of the second thermoelectric module 120-2.

As configured as described above, the first thermoelectric module 120-1 and the second thermoelectric module 120-2 may implement a hot side (or a cold side) on the first substrate 121.

Meanwhile, the polarity of the terminal of the first diode 130-1 connected to the electrode of the first thermoelectric module 120-1 may be the same as that of the third diode 130-3 connected to the electrode of the second thermoelectric module 120-2, and the polarity of the terminal of the second diode 130-2 connected to the electrode of the first thermoelectric module 120-1 may be the same as that of the fourth diode 130-4 connected to the electrode of the second thermoelectric module 120-2.

In addition, when the first switch 140-1 is connected to the first diode 130-1, if the second switch 140-2 is connected to the third diode 130-3 and the first switch 140-1 is connected to the second diode 130-2, the second switch 140-2 may be connected to the fourth diode 130-4.

Meanwhile, the exemplary embodiment of the present invention describes a case in which two thermoelectric modules 120 are provided; however, it is obvious that the thermoelectric apparatus may be implemented by including three or more thermoelectric modules.

The thermoelectric apparatus according to the present invention can use AC power as an energy source of the thermoelectric module with only minimum components, thereby making it possible to make the thermoelectric apparatus miniaturized and light and reduce manufacturing costs thereof.

In addition, the thermoelectric function is performed using the entire phase of AC power, thereby making it possible to improve energy efficiency and thermoelectric performance.

The cooling function or the heating function may be selective implemented on the same surface, even without a change in a circuit or a structure thereof, thereby making it possible to improve utilization of the thermoelectric apparatus.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A thermoelectric apparatus, comprising:
a power supply unit outputting AC power;
a plurality of thermoelectric modules including substrates, electrodes and thermoelectric elements;
a rectifier configured of a pair of diodes each connected in series to one side of the respective thermoelectric modules, the diodes having a different direction; and
a path selection unit selecting any one of the pair of diodes having a different direction and connecting the diode to the power supply unit.

2. The thermoelectric apparatus according to claim 1, wherein the plurality of thermoelectric modules share at least one substrate.

3. The thermoelectric apparatus according to claim 1, wherein the rectifier is provided in each of the thermoelectric modules.

4. The thermoelectric apparatus according to claim 3, wherein the path selection unit is provided in each of the thermoelectric modules.

5. The thermoelectric apparatus according to claim 1, wherein the rectifier is connected to an electrode contacting only an N-type semiconductor of the plurality of thermoelectric modules.

6. The thermoelectric apparatus according to claim 1, wherein the rectifier is connected to an electrode contacting only a P-type semiconductor of the plurality of thermoelectric modules.

7. A thermoelectric apparatus, comprising:
a power supply unit outputting AC power;
a first thermoelectric module and a second thermoelectric module including substrates, electrodes and thermoelectric elements;
a first diode connected in series to one side of the first thermoelectric module;
a second diode connected in series to one side of the first thermoelectric module, having a direction opposite to the first diode;
a third diode connected in series to one side of the second thermoelectric module;
a fourth diode connected in series to one side of the second thermoelectric module, having a direction opposite to the third diode;
a first switch connecting one selected from the first diode and the second diode to the power supply unit; and
a second switch connecting one selected from the third diode and the fourth diode to the power supply unit.

8. The thermoelectric apparatus according to claim 7, wherein the first thermoelectric module and the second thermoelectric module share at least one substrate.

9. The thermoelectric apparatus according to claim 7, wherein the first diode and the second diode are provided in the first thermoelectric module, and the third diode and the fourth diode are provided in the second thermoelectric module.

10. The thermoelectric apparatus according to claim 9, wherein the first switch is provided in the first thermoelectric module, and the second switch is provided in the second thermoelectric module.

11. The thermoelectric apparatus according to claim 7, wherein the first diode and the second diode are connected to an electrode contacting only an N-type semiconductor of the first thermoelectric module, and the third diode and the fourth diode are connected to an electrode contacting only an N-type semiconductor of the second thermoelectric module.

12. The thermoelectric apparatus according to claim 7, wherein the first diode and the second diode are connected to an electrode contacting only a P-type semiconductor of the first thermoelectric module, and the third diode and the fourth diode are connected to an electrode contacting only a P-type semiconductor of the second thermoelectric module.

13. The thermoelectric apparatus according to claim 7, wherein the polarity of the terminal of the first diode connected to the electrode of the first thermoelectric module is the same as that of the third diode connected to the electrode of the second thermoelectric module, and the polarity of the terminal of the second diode connected to the electrode of the first thermoelectric module is the same as that of the fourth diode connected to the electrode of the second thermoelectric module.

14. The thermoelectric apparatus according to claim 7, wherein when the first switch is connected to the first diode, the second switch is connected to the third diode, and when the first switch is connected to the second diode, the second switch is connected to the fourth diode.
